(19) United States
(12) Patent Application Publication
(10) Pub. No.: US 2014/0145323 A1
(43) Pub. Date: May 29, 2014

(54) LAMINATION LAYER TYPE SEMICONDUCTOR PACKAGE

(71) Applicant: Samsung Electro-Mechanics Co., Ltd., Suwon-si (KR)

(72) Inventors: Kyung Ho LEE, Suwon-si (KR); Hyun Bok KWON, Suwon-si (KR); Seung Wan WOO, Suwon-si (KR); Young Nam HWANG, Suwon-si (KR); Suk Jin HAM, Suwon-si (KR); Po Chul KIM, Suwon-si (KR); So Hyang EUN, Suwon-si (KR); Se Jun PARK, Suwon-si (KR)

(73) Assignee: SAMSUNG ELECTRO-MECHANICS CO., LTD., Suwon-si (KR)

(21) Appl. No.: 14/089,724

(22) Filed: Nov. 25, 2013

(30) Foreign Application Priority Data
Nov. 26, 2012 (KR) 10-2012-0134493

(51) Int. Cl. H01L 23/373

(52) U.S. Cl. CPC H01L 23/373
USPC 257/692

(57) ABSTRACT

Disclosed herein is a lamination layer type semiconductor package, and more particularly, a lamination layer type semiconductor package capable of maintaining a thickness of a package on package structure at a minimum and minimizing a warpage defect by mounting two chips so as to correspond to each other. The lamination layer type semiconductor package includes: an upper package having an upper flip chip mounted on an upper substrate; a lower package having a lower flip chip mounted on a lower substrate and disposed so as to closely adhere the upper flip chip and the lower flip chip to each other; a heat dissipation adhesive member adhesively fixing the upper flip chip and the lower flip chip and dissipating heat generated from the upper flip chip and the lower flip chip; and a molding member molding between the upper substrate and the lower substrate.

### CROSS REFERENCE(S) TO RELATED APPLICATIONS

This application claims the benefit under 35 U.S.C. Section 119 of Korean Patent Application Serial No. 10-2012-0134493, entitled “Lamination Layer Type Semiconductor Package” filed on Nov. 26, 2012, which is hereby incorporated by reference in its entirety into this application.

### BACKGROUND OF THE INVENTION

1. Technical Field

The present invention relates to a lamination layer type semiconductor package, and more particularly, to a lamination layer type semiconductor package capable of maintaining a thickness of a package on package structure at a minimum and minimizing a warpage defect by mounting two chips so as to correspond to each other.

2. Description of the Related Art

In general, a demand for portable information communication devices has recently increased in a market of electronic products. Therefore, various semiconductors and electric and electronic parts embedded in those products also tend to be manufactured so as to be smaller, lighter and thinner.

In order to manufacture an electronic component package applied to the above-mentioned electronic product, the electronic parts and connection terminals are generally connected by a wire bonding and are packaged using resin.

In addition, a package on package (POP) structure is recently applied to a semiconductor package mounted on a mobile.

The above-mentioned semiconductor package has a memory package connected to an upper portion thereof and an AP package connected to a lower portion thereof by a stack ball to form the package on package structure.

A process of manufacturing a semiconductor package according to the related art manufactures an upper package and a lower package, respectively, and then laminates them to connect to each other.

That is, on the upper package, after manufacturing a wiper, a die attachment is performed and a wire bonding and a molding are performed. On the lower package, after manufacturing the wiper, a flip chip is mounted and is molded.

When both the upper package and the lower package are completed, they are laminated and then integrated by performing a reflow process.

However, the package on package structure according to the related art separately performs mold processes for molding chips and generates warpage at the upper package and the lower package at the time of mounting on a board of the mobile due to characteristic of a structure on which the upper package and the lower package are stacked, such that defect may be caused.

### RELATED ART DOCUMENT

### Patent Document

(Patent Document 1) Cited Reference: Korean Patent Laid-Open Publication No. 2005-0097648

### SUMMARY OF THE INVENTION

An object of the present invention is to provide a lamination layer type semiconductor package capable of maintaining a thickness of a package on package structure at a minimum and minimizing warpage defect by mounting two chips so as to correspond to each other.

Another object of the present invention is to provide a lamination layer type semiconductor package capable of securing reliability of a product by decreasing the warpage defect caused by a mold process at the time of molding the chips.

According to an exemplary embodiment of the present invention, there is provided a lamination layer type semiconductor package, including: an upper package having an upper flip chip mounted on an upper substrate; a lower package having a lower flip chip mounted on a lower substrate and disposed so as to closely adhere the upper flip chip and the lower flip chip to each other; a heat dissipation adhesive member adhesively fixing the upper flip chip and the lower flip chip and dissipating heat generated from the upper flip chip and the lower flip chip; and a molding member molding between the upper substrate and the lower substrate.

The upper flip chip may be connected to the upper substrate by a solder bump and the lower flip chip may be connected to the lower substrate by a solder bump.

The upper substrate and the lower substrate may have stack balls formed therebetween, the stack ball electrically connecting the upper substrate and the lower substrate to each other.

The stack ball may be configured at both sides of the upper flip chip and the lower filp chip, respectively and the molding member may be an EMC molding.

The heat dissipation adhesive member may be a film material having high thermal conductivity coefficient and the heat dissipation adhesive member may be an epoxy material having high thermal conductivity coefficient.

### BRIEF DESCRIPTION OF THE DRAWINGS

FIGS. 1A to 1E are illustration views showing processes of manufacturing a lamination layer type semiconductor package according to an exemplary embodiment of the present invention; and

FIG. 2 is an illustration view showing a process of dissipating heat of the lamination layer type semiconductor package according to the exemplary embodiment of the present invention.

### DESCRIPTION OF THE PREFERRED EMBODIMENTS

Hereinafter, a lamination layer type semiconductor package according to an exemplary embodiment of the present invention will be described in detail with reference to the accompanying drawings.

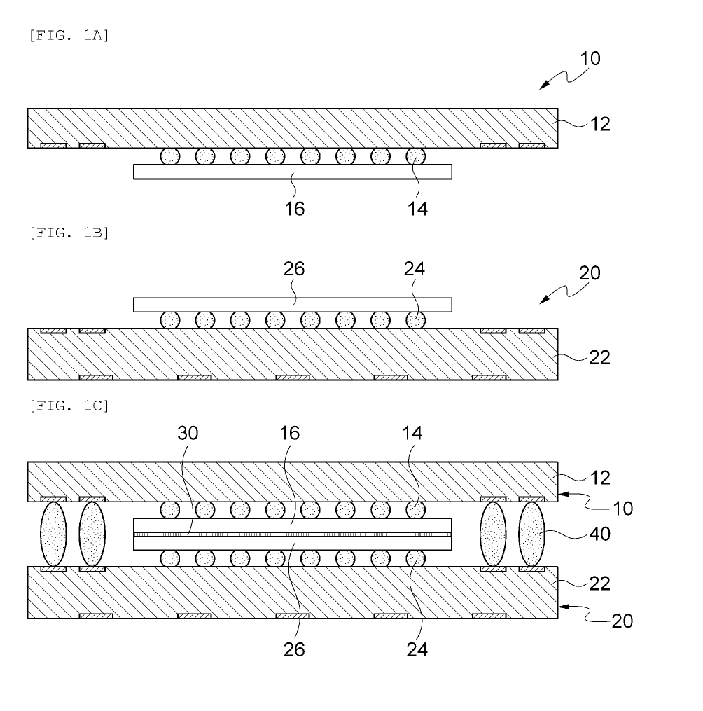

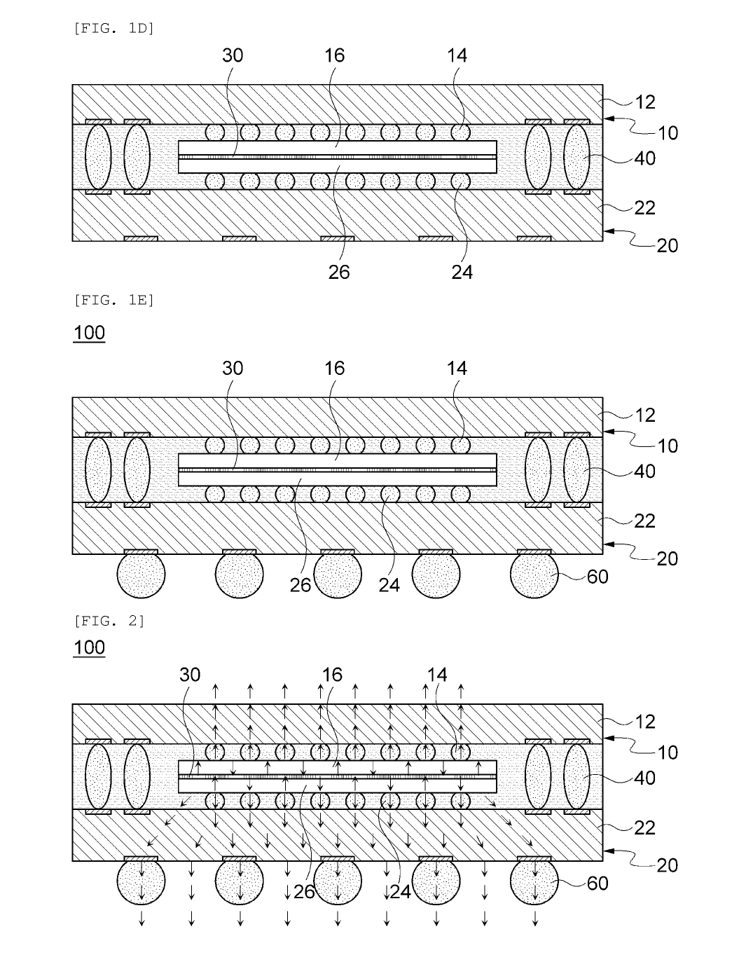

FIGS. 1A to 1E are illustration views showing processes of manufacturing a lamination layer type semiconductor package according to an exemplary embodiment of the present invention and FIG. 2 is an illustration view showing a process of dissipating heat of the lamination layer type semiconductor package according to the exemplary embodiment of the present invention.

As shown, the lamination layer type semiconductor package 100 according to the exemplary embodiment of the present invention includes an upper package 10 having an upper flip chip 16 mounted thereon, a lower package 20 having a lower flip chip 26 mounted thereon, a heat dissipation adhesive member 30 adhesively fixing the upper flip chip 16 and the lower flip chip 26 to each other, and a molding member 50 molding between an upper substrate 12 and a lower substrate 22.

The upper package 10 is configured by configuring solder bumps 14 on a surface of the upper substrate 12, seating the upper flip chip 16 on the solder bump 14, and then performing a reflow process.

The upper flip chip 16 may be several types of chips such as a memory, a CPU, or the like which may be electrically connected to the upper substrate 12 through the solder bump 14.

The lower package 20 is configured by configuring solder bumps 24 on a surface of the lower substrate 22, seating the lower flip chip 26 on the solder bump 24, and then performing the reflow process, similar to the upper package 10.

The lower flip chip 26 may be several forms of chips such as a memory, a CPU, or the like which may be electrically connected to the lower substrate 22 through the solder bump 24.

As described above, after the upper package 10 and the lower package 20 are manufactured through the respective processes, the upper flip chip 16 is rotated so as to be closely adhered to the lower flip chip 26.

In this case, the heat dissipation adhesive member 30 is inserted between the upper flip chip 16 and the lower flip chip 26 so that the upper flip chip 16 and the lower flip chip 26 may be adhered to each other and heat generated therefrom may be dissipated to the outside.

The heat dissipation adhesive member 30 may be manufactured as a film material or an epoxy material having a high thermal conductivity coefficient. That is, the heat dissipation adhesive member 30 serves to fix the upper flip chip 16 and the lower flip chip 26 to each other and absorb the heat generated from the upper flip chip 16 and the lower flip chip 26, and then dissipate again the heat to the outside of the substrate by thermal conduction.

In addition, stack balls 40 are formed between the upper flip chip 16 and the lower flip chip 26 so as to electrically connect the upper substrate 12 and the lower substrate 22 to each other.

In a state in which the stack ball 40 is formed on any one of the upper package 10 and the lower package 20 and the upper package 10 is rotated so as to be closely adhered to the lower package 20, the upper substrate 12 and the lower substrate 22 are connected to each other by the reflow process.

After the upper substrate 12 and the lower substrate 22 are electrically connected to each other through the stack ball 40, a molding member 50 is introduced between the upper package 10 and the lower package 20. The molding member 50 is an EMC molding, and since the EMC molding is a known molding, a detailed description thereof will be omitted.

When the molding member 50 is introduced and the upper package 10 and the lower package 20 are integrated, solder balls 60 may be further formed so that the integrated upper package 10 and lower package 20 are mounted on a board of an electronic apparatus.

The lamination layer type semiconductor package 100 according to the exemplary embodiment of the present invention configured as described above maintains a firmly fixed state since the upper flip chip 16 and the lower flip chip 26 are fixed to each other by the heat dissipation adhesive member 30 and the molding member 50 is introduced between the upper substrate 12 and the lower substrate 22.

Once an action starts in a state in which the upper flip chip 16 and the lower flip chip 26 are mounted on the electronic apparatus, the upper flip chip 16 and the lower flip chip 26 start heating simultaneously with the action.

As such, the heat generated from the upper flip chip 16 and the lower flip chip 26 is absorbed by the heat dissipation adhesive member 30 because the thermal conductivity coefficient of the heat dissipation adhesive member 30 is higher than that of the upper flip chip 16 and the lower flip chip 26, as shown in FIG. 2.

The heat dissipation adhesive member 30 absorbing the heat again conducts the heat through the upper flip chip 16 and the lower flip chip 26, and the upper flip chip 16 and the lower flip chip 26 conduct the heat to the solder bump 14 or 24.

The solder bump 14 or 24 to which the heat is conducted as described above may conduct the heat to the upper substrate 12 and the lower substrate 22 again to radiate the heat generated from the upper flip chip 16 and the lower flip chip 26.

In this case, all the heat generated from the upper flip chip 16 and the lower flip chip 26 is not conducted to the heat dissipation adhesive member 30, but a portion thereof is conducted to the solder bump 14 or 24 so as to be conducted to the upper substrate 12 and the lower substrate 22.

Therefore, the lamination layer type semiconductor package 100 according to the exemplary embodiment of the present invention may form a package structure which was integrated by separately performing molding and laminating, by one molding process, such that a work process may be decreased and the warpage defect generated at the upper package 10 and the lower package 20 at the time of mounting the upper package 10 and the lower package 20 on the board of the electronic apparatus may be efficiently decreased.

According to the exemplary embodiment of the present invention, the lamination layer type semiconductor package may maintain the thickness of the package on package structure at a minimum by mounting the two chips so as to correspond to each other, thereby making it possible to implement a slimmer mobile.

In addition, the reliability of the product may be secured by decreasing the warpage defect caused by the mold process at the time of molding the chips.

Hereinabove, although the lamination layer type semiconductor package according to the exemplary embodiment of the present invention has been described, the present invention is not limited thereto, but may be variously modified and altered by those skilled in the art.

What is claimed is:

1. A lamination layer type semiconductor package, comprising:
an upper package having an upper flip chip mounted on an upper substrate;
a lower package having a lower flip chip mounted on a lower substrate and disposed so as to closely adhere the upper flip chip and the lower flip chip to each other;
a heat dissipation adhesive member adhesively fixing the upper flip chip and the lower flip chip and dissipating heat generated from the upper flip chip and the lower flip chip; and
a molding member introduced between the upper substrate and the lower substrate.

2. The lamination layer type semiconductor package according to claim 1, wherein the upper flip chip is connected to the upper substrate by a solder bump.

3. The lamination layer type semiconductor package according to claim 1, wherein the lower flip chip is connected to the lower substrate by a solder bump.

4. The lamination layer type semiconductor package according to claim 1, wherein the upper substrate and the lower substrate have stack balls formed therebetween, the stack ball electrically connecting the upper substrate and the lower substrate to each other.

5. The lamination layer type semiconductor package according to claim 1, wherein the molding member is an EMC molding.

6. The lamination layer type semiconductor package according to claim 1, wherein the heat dissipation adhesive member is a film material having high thermal conductivity coefficient.

7. The lamination layer type semiconductor package according to claim 1, wherein the heat dissipation adhesive member is an epoxy material having high thermal conductivity coefficient.

8. The lamination layer type semiconductor package according to claim 1, wherein the lower substrate is provided with a solder ball so as to be mounted on a board of an electronic apparatus.
